(19) United States
(12) Patent Application Publication
(10) Pub. No.: US 2003/0070825 A1
(43) Pub. Date: Apr. 17, 2003

(54) Compact peripheral component interconnect keyed filler panel

(76) Inventors: Michael J. Greenside, Granite Bay, CA (US); Sean A. Cerniglia, Cool, CA (US)

Correspondence Address: HEWLETT-PACKARD COMPANY, Intellectual Property Administration, P.O. Box 272400, Fort Collins, CO, 80527-2400, US

(21) Appl. No.: 09/976,997

(22) Filed: Oct. 11, 2001

(51) Int. Cl. H05K 9/00

(52) U.S. Cl. 174/35 R

(57) ABSTRACT

A keyed filler panel assembly for reducing interference generating movement of a filler panel body with respect to a chassis is disclosed. In one embodiment, the present invention is comprised of a filler panel body. The present embodiment is further comprised of a locating element which is coupled to the filler panel body. The locating element is adapted to orient the filler panel body with respect to a chassis such that interference generating movement of the filler panel body is reduced.

### TECHNICAL FIELD

The present claimed invention relates to the field of computer chassis structures. More specifically, the present claimed invention relates to filler panels employed in conjunction with computer chassis structures.

### BACKGROUND ART

Filler panels are conventionally used in conjunction with various computer chassis for electromagnetic interference (EMI) containment as well as for sealing of the computer chassis/card cage for thermal (e.g. forced airflow) cooling purposes. Specifically, in a conventional computer chassis/card cage assembly, multiple slots are available to receive a corresponding printed circuit assembly (PCA). The filler panels are attached to the computer chassis to enclose or seal off regions/slots of the computer chassis which do not have a printed circuit assembly (PCA) disposed therein. Typically, conventional filler panels are attached to the computer chassis using captive screws. The captive screws are disposed on the filler panels at locations corresponding to mounting holes residing within the computer chassis.

The location and the spacing of mounting holes within the computer chassis (and the corresponding location of the captive screws on the filler panels) are often defined by an industry standard. Typical standards include, for example, the compact peripheral component interconnect (CPCI) standard, and the VersaModular Eurocard (VME) standard. For example, the CPCI standard dictates that the gap between adjacent units (e.g. adjacent filler panels, adjacent PCAs, or a PCA and an adjacent filler panel) be nominally set at 0.30 millimeters. Unfortunately, industry standard captive screws allow the filler panel to be mispositioned by more than 1.0 millimeter. For purposes of the present application, this mispositioning with respect to the computer chassis, caused in some cases by the use of captive screws, is referred to as interference generating movement. During use, the interference generating movement of the filler panels can deleteriously prevent insertion of a PCA or a filler panel. That is, interference generating movement of one or more filler panels can result in insufficient space in a neighboring slot such that a filler panel or a PCA will not fit in the compromised gap.

With reference now to Prior Art FIG. 1, an example of a compromised gap produced as a result of interference generating movement of a filler panel is clearly illustrated. As shown in Prior Art FIG. 1, a portion of a computer chassis 100 is depicted having mounting holes, typically shown as 102, therein. A filler panel 104 is shown coupled to computer chassis 100 and, for purposes of illustration, filler panel 104 is depicted as being coupled to computer chassis 100 without any substantial interference generating movement. Another filler panel 106 is also shown coupled to computer chassis 100. In this example, filler panel 106 is depicted as being coupled to computer chassis 100 with substantial interference generating movement due to the use of captive screws 107a and 107b. Specifically, filler panel 106 is depicted as having been mispositioned in a direction towards neighboring gap 108 and filler panel 104. Dotted line 110 illustrates the desired or nominal location of filler panel 106 assuming no interference generating movement. Because of the interference generating movement of filler panel 106, the width, w, of gap 108 is less than the width of a filler panel or a PCA. Hence, it is no longer possible to readily place a filler panel or a PCA into gap 108. Additionally, the width of gap 108 may be even further comprised (i.e. reduced) in the case where filler panel 104 suffers from interference generating movement which mispositions filler panel 104 in a direction towards neighboring gap 108 and filler panel 106.

At present, one approach to fix the problem described above, is to first have all of the necessary filler panels loosely connected to the computer chassis. Once all of the filler panels are in place, the filler panels are then carefully tightened to the computer chassis in order to insure that interference generating movement is reduced as much as possible. However, such a method is time-consuming, cumbersome, and lacks the desired “Design for Manufacturability”.

The problem described in conjunction with Prior Art FIG. 1 is particularly egregious in light of the increased prevalence of “hot swapping”. Hot swapping refers to a process in which a PCA is added to or removed from the computer chassis without powering down the system. With hot swapping, it is imperative that interference generating movement is reduced in order to facilitate rapid and perhaps frequent removal and addition of PCAs and filler panels.

One prior art attempt to resolve the problem of interference generating movement involves customizing a computer chassis with a non-standard sheet metal interface having predefined openings formed therein. Specially designed filler panels are also employed in conjunction with the non-standard customized computer chassis. Such an approach has severe drawbacks associated therewith. For example, a non-standard customized chassis allows DFM tolerancing that makes is very difficult to hold CPCI standard specifications. Furthermore, limiting customers to the use of one particular design/maker of filler panels is not favorable.

Thus, the need has arisen for a filler panel attachment method and apparatus which reduces interference generating movement of a filler panel with respect to a chassis. Still another need exists for a filler panel attachment method and apparatus which meets the above need and which facilitates hot swapping of PCA cards. Yet another need exists for a filler panel attachment method and apparatus which meets the above needs and which can be adapted to readily interface with industry standard components and meet industry standard specifications.

### DISCLOSURE OF THE INVENTION

The present invention provides a filler panel attachment method and apparatus which reduces interference generating movement of a filler panel with respect to a chassis. The present invention also provides a filler panel attachment method and apparatus which achieves the above accomplishment and which facilitates hot swapping of PCA cards. The present invention also provides a filler panel attachment method and apparatus which achieves the above accomplishments and which can be adapted to readily interface with industry standard components and meet industry standard specifications.

Specifically, a keyed filler panel assembly for reducing interference generating movement of a filler panel body with respect to a chassis is disclosed. In one embodiment, the present invention is comprised of a filler panel body. The present embodiment is further comprised of a locating element which is coupled to the filler panel body. The locating element is adapted to orient the filler panel body with respect to a chassis such that interference generating movement of the filler panel body is reduced.

These and other technical advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings, which are incorporated in and form a part of this specification, illustrate embodiments of the invention and, together with the description, serve to explain the principles of the invention:

PRIOR ART FIG. 1 is a front view of a plurality of conventional filler panels coupled to a computer chassis wherein interference generating movement has compromised the gap between to filler panels.

FIG. 2 is a perspective view of a keyed filler panel assembly in accordance with one embodiment of the present claimed invention.

FIG. 3 is a perspective view of another embodiment of a keyed filler panel assembly in which the attaching device is comprised of a captive screw and an underlying D-clip in accordance with one embodiment of the present claimed invention.

FIG. 4 is a side view of a locating element in accordance with one embodiment of the present claimed invention.

FIG. 5 is a side view of a locating element including a retaining portion in accordance with another embodiment of the present claimed invention.

FIG. 6 is a perspective view of a keyed filler panel assembly in which the top surface of the head portion of a locating element is flush with the receiving surface of a filler panel body in accordance with one embodiment of the present claimed invention.

FIG. 7 is a front view of a plurality of keyed filler panel assemblies coupled to a computer chassis wherein interference generating movement has reduced in accordance with one embodiment of the present claimed invention.

FIG. 8 is a flow chart of steps performed in accordance with one embodiment of the present claimed invention.

The drawings referred to in this description should be understood as not being drawn to scale except if specifically noted.

### BEST MODES FOR CARRYING OUT THE INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

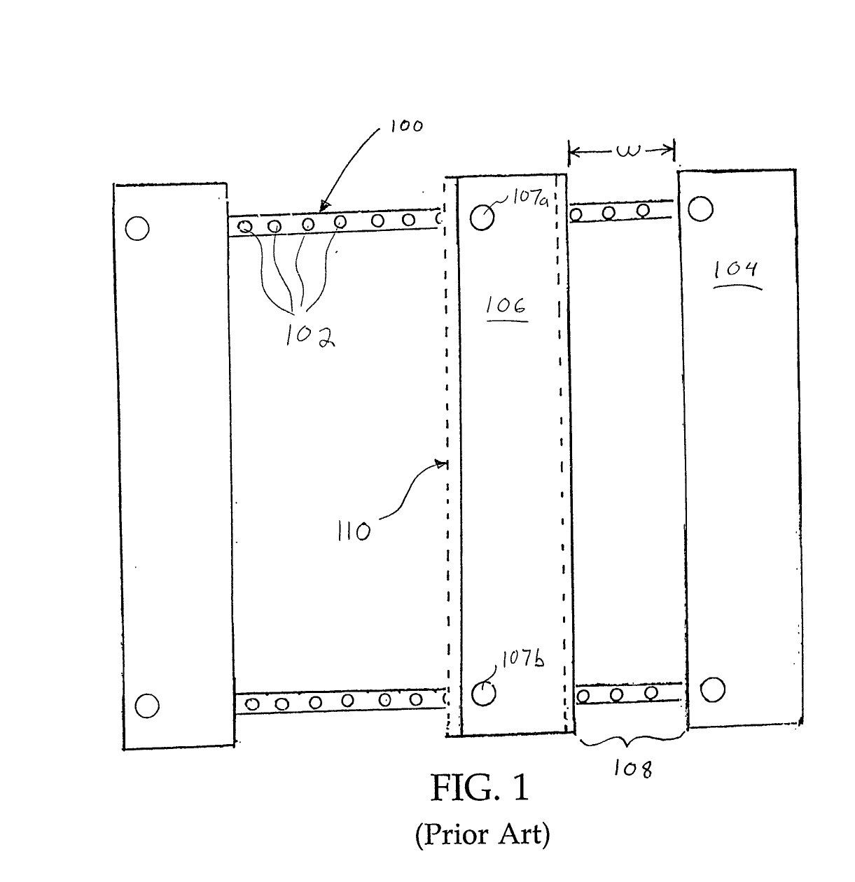

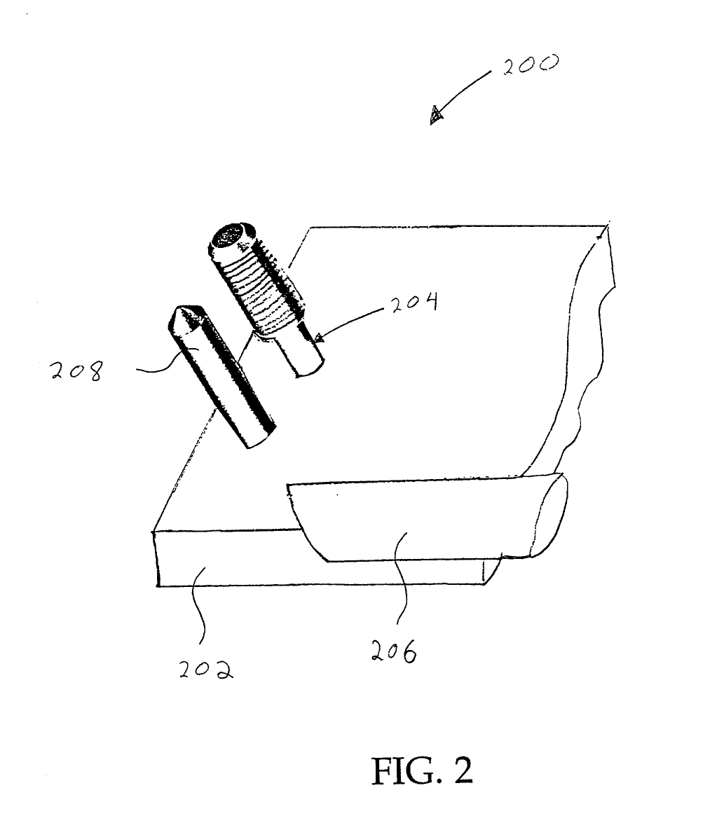

With reference now to FIG. 2, a perspective view of a keyed filler panel assembly 200 in accordance with one embodiment of the present claimed invention is shown. The following discussion will begin with a detailed description of the physical characteristics of the present keyed filler panel assembly. The discussion will then contain a detailed description of the use and operation of the present keyed filler panel assembly. Regarding the physical structure of the present keyed filler panel assembly, for purposes of clarity, only one end of the keyed filler panel assembly 200 is shown in FIG. 2. In the present embodiment keyed filler panel assembly 200 includes a filler panel body 202. Importantly, as will be discussed in detail below, in one embodiment, filler panel body 202 is a filler panel formed having dimensions and characteristics which are in compliance with an industry standard such as, for example, the compact peripheral component interconnect (CPCI) standard, and the VersaModular Eurocard (VME) standard.

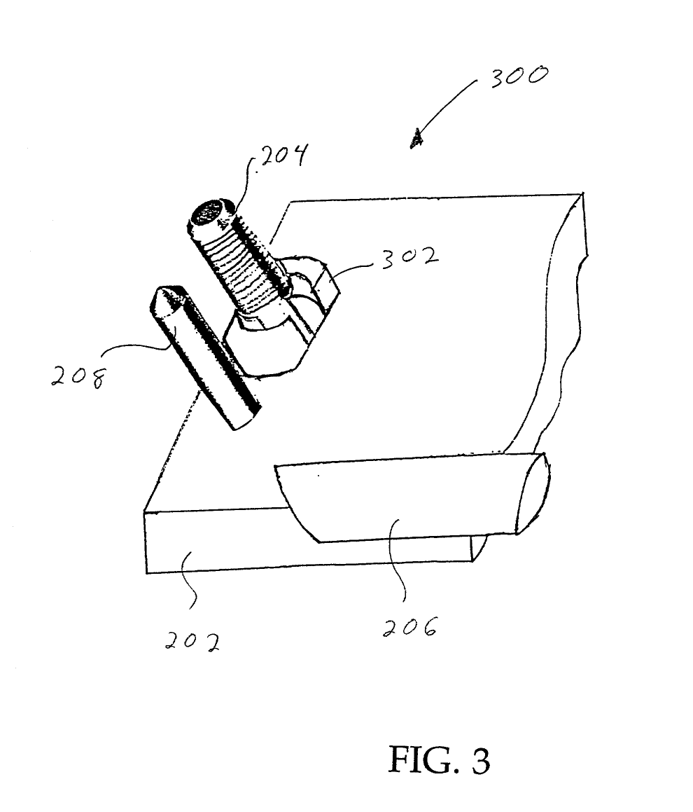

Referring still to FIG. 2, keyed filler panel assembly 200 also includes an attaching device 204 which is adapted to be coupled to filler panel body 202. In one embodiment, attaching device 204 is comprised of a captive screw. Attaching device 204 is ultimately employed to removably couple filler panel body 202 to a computer chassis. Importantly, as will be discussed in detail below, in one embodiment, attaching device 204 is an attaching device formed having dimensions and characteristics which are in compliance with an industry standard such as, for example, the CPCI standard, and the VME standard. Also, although a captive screw is specifically mentioned as the attaching device 204 in the present embodiment, the present invention is also well suited to use with various other types of attaching devices including, for example, D-clips, snaps, and the like. FIG. 3 illustrates another embodiment of a keyed filler panel assembly 300 in accordance with the present invention in which the attaching device is comprised of a captive screw 204 and an underlying D-clip 302. For purposes of brevity and clarity each of the numerous possibilities of attaching devices are not shown in the present Figures.

With reference again to FIG. 2, keyed filler panel assembly 200 of the present embodiment also includes an electromagnetic interference (EMI) shield portion 206 coupled to filler panel body 202. EMI shield portion 206 is employed to prevent EMI leakage from a chassis to which keyed filler panel assembly 200 is ultimately coupled. In one embodiment, EMI shield portion 206 is removably coupleable to filler panel body 202. The present embodiment is also well suited to an embodiment in which EMI shield portion 206 is integral with filler panel body 202.

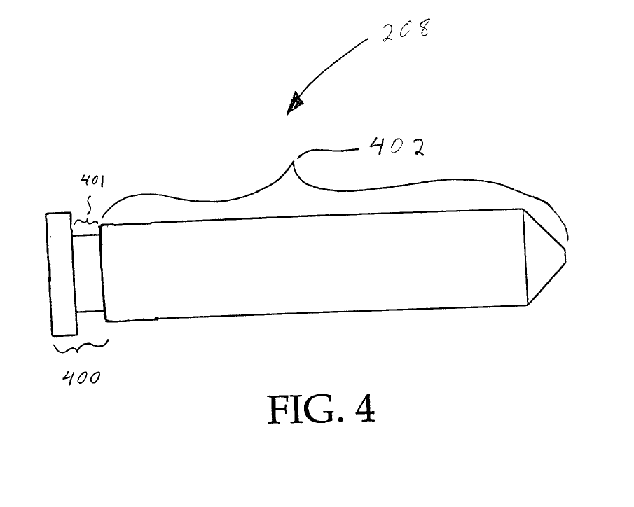

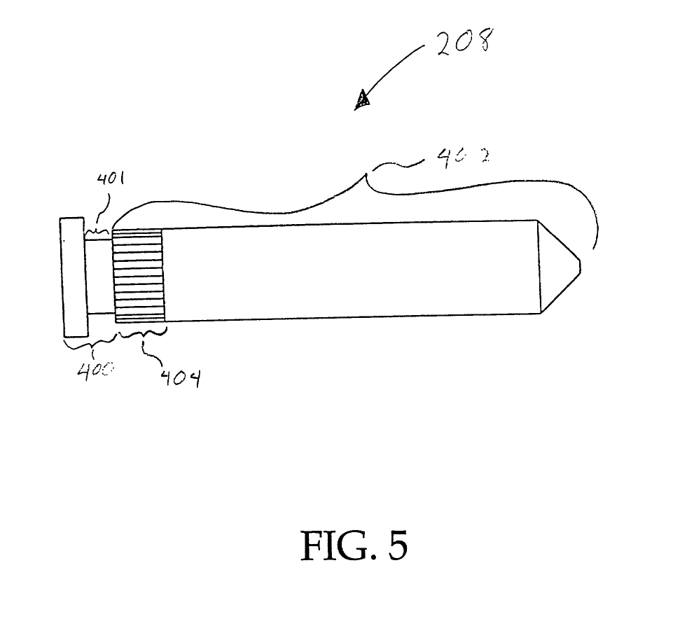

Keyed filler panel assembly 200 of the present invention also includes a locating element 208 which is coupled to filler panel body 202. FIG. 4 shows a side view of one embodiment of locating element 208. As shown in FIG. 4, in one embodiment, locating element 208 is comprised of a head portion 400, and an insertion portion 402. As will be discussed below in detail, in one embodiment, head portion 400 is adapted to be arranged flush with filler panel body 202 of FIGS. 2 and 3. Insertion portion 402 of locating element 208 is adapted to be inserted in an opening (e.g. a mounting hole) in a computer chassis to reduce interference generating movement of filler panel body 202 of FIGS. 2 and 3 with respect to the computer chassis. FIG. 5 illustrates another embodiment of the present invention in which locating element 208 also includes a retention portion 404 which is coupled to head portion 400. Retention portion 404 is adapted to enhance coupling of locating element 208 and filler panel body 202 of FIGS. 2 and 3. As will be described in detail below, locating element 208 is adapted to orient filler panel body 202 with respect to a computer chassis such that interference generating movement of filler panel body 202 is reduced.

### USE AND OPERATION

The following is a detailed description of the use and operation of the present keyed filler panel assembly. With reference again to FIGS. 2 and 3, in one embodiment of the present invention, locating element 208 is coupled to a filler panel body such as filler panel body 202. In one embodiment, locating element 208 is inserted through filler panel body 202 proximate to the location where attaching device 204 is or will be disposed. In the present embodiment, locating element 208 rigidly extends from filler panel body 202 and does not shift in position with respect to filler panel body 202.

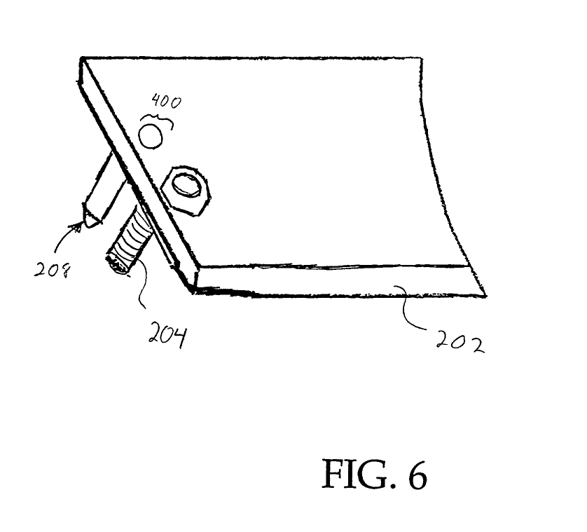

In one embodiment of the present invention, the locating element 208 is coupled to filler panel body 202 such that the top surface of head portion 400 is flush with the receiving surface of filler panel body 202. FIG. 6 illustrates an embodiment in which the top surface of head portion 400 is flush with the receiving surface of filler panel body 202. In one embodiment, the shape of head portion 400, including recessed region 401, assists in the coupling of locating element 208 to a filler panel body. Also, as shown in FIG. 5, in one embodiment of the present invention, retention portion 404 is comprised, for example, of ridges which assist in the rigid attachment of locating element 208 to filler panel body 202 by “gripping” the surrounding material comprising filler panel body 202.

Importantly, the present invention is well suited to attaching locating element 208 to a filler panel body which is formed without requiring remanufacturing, retooling, or redesigning of a filler panel body. Hence, locating element 208 of the present embodiment is well suited to use with legacy filler panel bodies. Therefore, unlike prior art approaches, the present embodiment does not limit customers to one particular design/maker of filler panels. Instead, the present embodiment allows customers to realize the beneficial reduced interference generating movement achieved with the present embodiment, while still utilizing the particular filler panel body of the customer's choice. As one example, locating element 208 is well suited to use with various types of filler panels having EMI shield portions which are removably coupled thereto, and also filler panels having EMI shield portions which are integral therewith. As another example, locating element 208 is well suited to use with various types of filler panels having various types of attaching devices including captive screw 204 and D-clip 302 of FIG. 3.

With reference again to FIGS. 2 and 3, in one embodiment of the present invention, locating element 208 is coupled to filler panel body 202 at a location such that insertion portion 402 of FIGS. 4 and 5 of locating element 208 will correspond to mounting holes disposed on a computer chassis. That is, in one such embodiment, locating element 208 is rigidly coupled to filler panel body 202 at a location such that insertion portion 402 will subsequently engage an opening in a computer chassis and, in so doing, firmly retain filler panel body 202 at a desired orientation with respect to the computer chassis. As a result, subsequent to the insertion of locating element 208 into an opening in computer chassis, the present invention allows attaching device 204 to be coupled to the computer chassis without concern for deleterious interference generating movement.

Furthermore, in one embodiment of the present invention, locating element 208 is coupled to filler panel body 202 at a location which corresponds to an industry standard such as, for example, the compact peripheral component interconnect (CPCI) standard or the VersaModular Eurocard (VME) standard. In such an embodiment, locating element 208 is rigidly coupled to filler panel body 202 at a location such that insertion portion 402 will subsequently engage an opening (e.g. a mounting hole) in a computer chassis and, in so doing, firmly retain filler panel body 202 at an orientation such that the nominal spacing specified by the standard between an adjacent device (e.g. another filler panel or a PCA) is obtained.

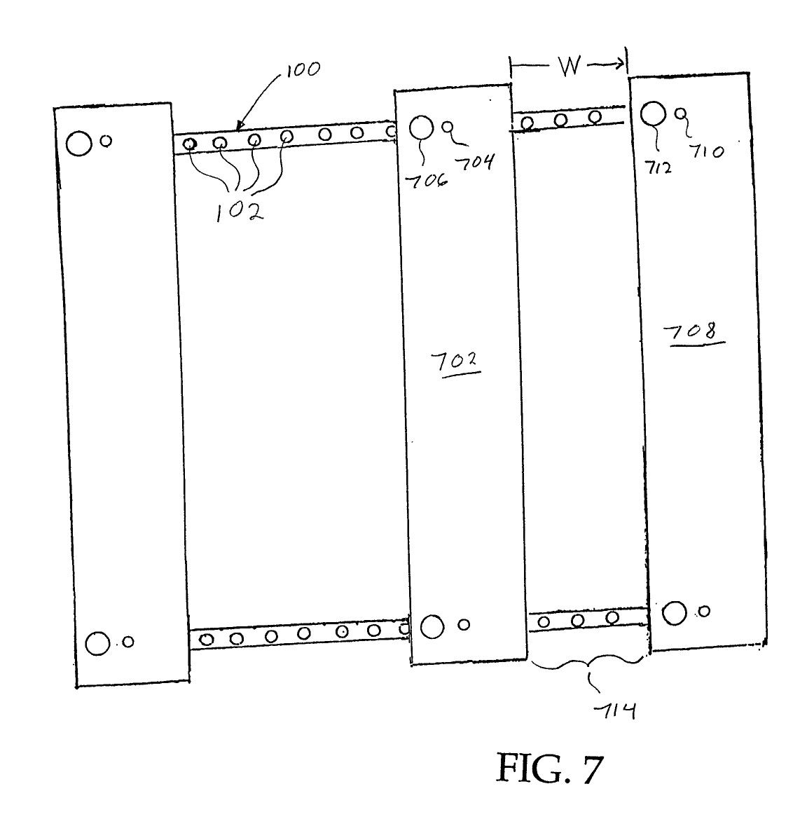

With reference now to FIG. 7, an example of an embodiment in which the present invention obtains the nominal spacing specified by a standard between adjacent units is illustrated. As shown in FIG. 7, a portion of a computer chassis 100 is depicted having mounting holes, typically shown as 102, therein. For purposes of the present example, the spacing between mounting holes 102 is defined by the CPCI standard. A keyed filler panel assembly 702 is shown coupled to computer chassis 100 using locating element 704 and an attaching device 706 in accordance with one embodiment of the present invention. As a result, keyed filler panel assembly 702 is coupled to computer chassis 100 without any substantial interference generating movement. Another keyed filler panel assembly 708 is also shown coupled to computer chassis 100. In this example, keyed filler panel assembly 708 is also coupled to computer chassis 100 using a locating element 710 and an attaching device 712 in accordance with one embodiment of the present invention. As a result, keyed filler panel assembly 708 is also coupled to computer chassis 100 without any substantial interference generating movement. Because the present embodiment reduces interference generating movement of keyed filler panel assemblies 702 and 708, the width, W, of gap 714 is maintained at the nominal width allotted by the standard to accommodate the insertion of another filler panel or a PCA. Hence, the present embodiment eliminates the unwanted interference found in the prior art.

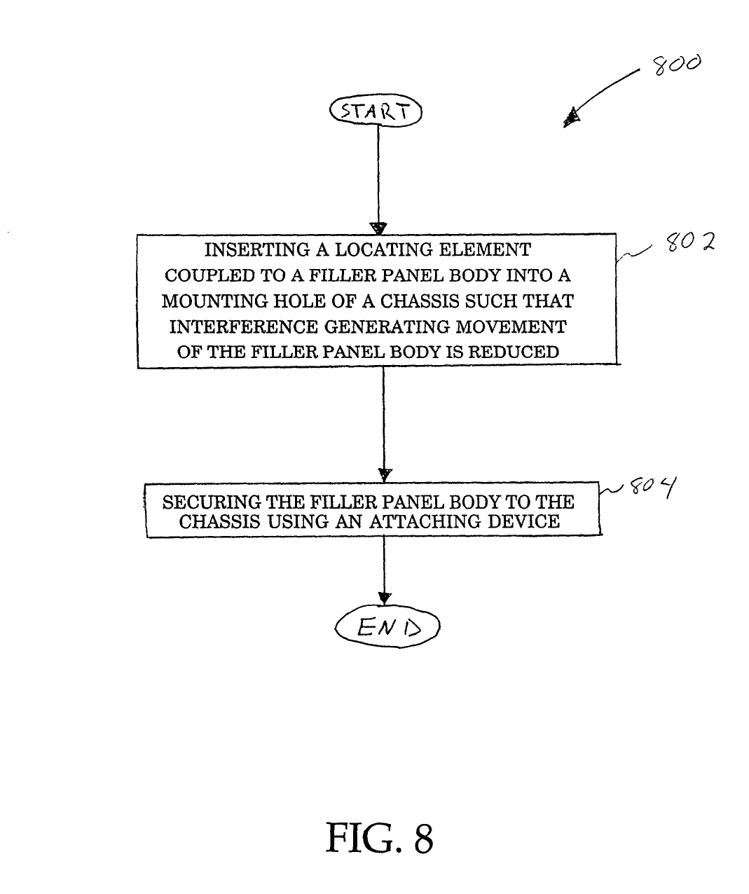

With reference now to FIG. 8, a flow chart 800 summarizing the steps performed in accordance with one embodiment of the present invention is shown. At step 802, the present embodiment inserts a locating element, coupled to a filler panel body, into a mounting hole of a chassis. As described in detail above, the locating element (e.g. locating element 208 of FIGS. 2 and 3) is adapted to orient a filler panel body with respect to the computer chassis such that interference generating movement of the filler panel body is reduced.

Next, at step 804, the present embodiment then secures the filler panel body of the keyed filler panel assembly to the chassis using an attaching device (e.g. captive screw 204 of FIGS. 2 and 3). Beneficially, the present embodiment eliminates the need to first have all of the necessary filler panels loosely connected to the computer chassis and then subsequently tighten the arranged filler panels. Instead, the present embodiment allows keyed filler panel assemblies to be independently coupled to a computer chassis at any time without concern for the subsequent attachment of additional filler panels or PCAs. Thus, the present invention achieves a “Design for Manufacturability” lacking in the prior art. Additionally, by reducing interference generating movement and enabling the independent attachment of keyed filler panel assemblies to a computer chassis, the present invention is extremely well suited to use in hot swapping environments.

Thus, the present invention provides a filler panel attachment method and apparatus which reduces interference generating movement of a filler panel with respect to a chassis. The present invention also provides a filler panel attachment method and apparatus which achieves the above accomplishment and which facilitates hot swapping of PCA cards. The present invention also provides a filler panel attachment method and apparatus which achieves the above accomplishments and which can be adapted to readily interface with industry standard components and meet industry standard specifications.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

1. A keyed filler panel assembly comprising:
a filler panel body; and
a locating element coupled to said filler panel body, said locating element adapted to orient said filler panel body with respect to a chassis such that interference generating movement of said filler panel body is reduced.

2. The keyed filler panel assembly of claim 1 further comprising:
an attaching device adapted to be coupled to said filler panel body, said attaching device for removably coupling said filler panel body to said chassis.

3. The keyed filler panel assembly of claim 1 further comprising:
an electromagnetic interference (EMI) shield portion coupled to said filler panel body, said EMI shield portion adapted to prevent EMI leakage from said chassis.

4. The keyed filler panel assembly of claim 1 wherein said locating element is coupled to said filler panel body at a location such that said locating element will insert into a mounting hole disposed on said chassis in accordance with a compact peripheral component interconnect (CPCI) standard.

5. The keyed filler panel assembly of claim 1 wherein said locating element is coupled to said filler panel body at a location such that said locating element will insert into a mounting hole disposed on said chassis in accordance with a VersaModular Eurocard (VME) standard.

6. The keyed filler panel assembly of claim 1 wherein said locating element is comprised of:
a head portion;
an insertion portion coupled to said head portion, said insertion portion adapted to be inserted into an opening in said chassis to reduce said interference generating movement of said filler panel body with respect to said chassis.

7. The keyed filler panel assembly of claim 6 wherein said locating element is coupled to said filler panel body such that said head portion is flush with said filler panel body.

8. The keyed filler panel assembly of claim 6 wherein said locating element is further comprised of:
a retention portion coupled to said head portion, said retention portion adapted to enhance coupling of said locating element and said filler panel body.

9. A method for preventing interference generating movement of a filler panel with respect to a chassis comprising:
a) inserting a locating element coupled to a filler panel body into a mounting hole of a chassis, said locating element adapted to orient said filler panel body with respect to said chassis such that interference generating movement of said filler panel body is reduced; and
b) securing said filler panel body to said chassis using an attaching device.

10. The method for preventing interference generating movement of a filler panel with respect to a chassis as recited in claim 9 wherein said step a) comprises inserting said locating element into said mounting hole wherein said mounting hole is disposed on said chassis in accordance with a compact peripheral component interconnect (CPCI) standard.

11. The method for preventing interference generating movement of a filler panel with respect to a chassis as recited in claim 9 wherein said step a) comprises inserting said locating element into said mounting hole wherein said mounting hole is disposed on said chassis in accordance with a VersaModular Eurocard (VME) standard.

12. The method for preventing interference generating movement of a filler panel with respect to a chassis as recited in claim 9 wherein said step a) comprises inserting said locating element having a head portion and an insertion portion coupled to said head portion into said mounting hole.

13. The method for preventing interference generating movement of a filler panel with respect to a chassis as recited in claim 12 wherein said step a) comprises inserting said locating element having a head portion flush with said filler panel body into said mounting hole.

14. The method for preventing interference generating movement of a filler panel with respect to a chassis as recited in claim 12 wherein said step a) comprises inserting said locating element including a retention portion coupled to said head portion into said mounting hole.

15. A keyed filler panel assembly comprising:
a filler panel body;
a locating element coupled to said filler panel body, said locating element adapted to orient said filler panel body with respect to a chassis such that interference generating movement of said filler panel body is reduced said locating element comprised of:
a head portion;
an insertion portion coupled to said head portion, said insertion
portion adapted to be inserted in an opening in said chassis to reduce
said interference generating movement of said filler panel body with
respect to said chassis; and
an attaching device adapted to be coupled to said filler panel body, said attaching device for removably coupling said filler panel body to said chassis.

16. The keyed filler panel assembly of claim 15 further comprising:
an electromagnetic interference (EMI) shield portion coupled to said filler panel body, said EMI shield portion adapted to prevent EMI leakage from said chassis.

17. The keyed filler panel assembly of claim 15 wherein said locating element is coupled to said filler panel body at a location such that said locating element will insert into a mounting hole disposed on said chassis in accordance with a compact peripheral component interconnect (CPCI) standard.

18. The keyed filler panel assembly of claim 15 wherein said locating element is coupled to said filler panel body at a location such that said locating element will insert into a mounting hole disposed on said chassis in accordance with a VersaModular Eurocard (VME) standard.

19. The keyed filler panel assembly of claim 15 wherein said locating element is coupled to said filler panel body such that said head portion is flush with said filler panel body.

20. The keyed filler panel assembly of claim 15 wherein said locating element is further comprised of:
a retention portion coupled to said head portion, said retention portion adapted to enhance coupling of said locating element and said filler panel body.
